(19) United States
(12) Patent Application Publication
(10) Pub. No.: US 2024/0287833 A1
(43) Pub. Date: Aug. 29, 2024

(54) DOOR HAVING STABLIZING MECHNISAM FOR LOCK, AND SUBSTRATE CARRIER

(71) Applicant: GUDENG PRECISION INDUSTRIAL CO., LTD., New Taipei (TW)

(72) Inventors: Ming-Chien CHIU, New Teipei (TW); Chia-Ho CHUANG, New Taipei (TW); Kuo-Hua LEE, New Taipei (TW); En-Nien SHEN, New Taipei (TW); Jyun-Ming LYU, New Taipei (TW)

(21) Appl. No.: 18/529,075

(22) Filed: Dec. 5, 2023

Related U.S. Application Data
(60) Provisional application No. 63/447,950, filed on Feb. 24, 2023.

(51) Int. Cl. E05B 17/00; E06B 3/48

(52) U.S. Cl. CPC E05B 17/0025; E06B 3/488; E05B 65/5215; E06B 1/52

(57) ABSTRACT

A door having a stabilization mechanism for a lock is provided. The door is suitable for a substrate carrier and includes a bottom plate, a cover and a limiting structure. The bottom plate and the cover define an accommodating space for accommodating a plurality of lock structures, each lock structure configured to move between an unlocked position and a locked position, an limiting structure is disposed between lock structure and the cover, and the limiting structure provides an elastic force corresponding to the displacement of the lock structures between the unlocked position and the locked position, such that the lock structures is maintained to move at a horizontal level under the elastic force. The structural design and configuration of the disclosure can prevent collision of substrate carrier or a problem of door drop resulted from the door falling to open/close smoothly.

### CROSS-REFERENCE TO RELATED APPLICATIONS

This divisional application claims priority under 35 U.S.C. § 119(a) on Patent Application No(s). 63/447,950 filed in U.S. on Feb. 24, 2023 the entire contents of which are hereby incorporated by reference.

### BACKGROUND OF THE INVENTION

### Field of the Invention

The present disclosure relates to a door having a lock and a substrate carrier, and more particularly to a door having a stabilization mechanism for a lock and a substrate carrier.

### Description of the Prior Art

FIG. 1 shows a conventional substrate carrier 10, for example, a front opening shipping box (FOSB) or a front opening unified pod (FOUP). The substrate carrier 10 usually has an outer housing 11 with an opening end 12 and a door 20. The door 20 has therein a plurality of lock structures 21 (shown in FIG. 2). The plurality of lock structures 21 can be moved between an unlocked position and a locked position by a rotating cam (not shown). When the plurality of lock structures 21 are at the unlocked position, the plurality of lock structures 21 are retracted and completely positioned inside the door 20, so that the door 20 can be placed in the opening end 12 of the outer housing 11 or be removed from the opening end 12 of the outer housing 11. When the plurality of lock structures 21 are at the locked position, end portions 24 of the plurality of lock structures 21 protrude out of the door 20 and operate in conjunction with a plurality of lock portions 14 (such as slots) disposed on an inner side of the opening end 12, so as to form a receiving space 13 for receiving multiple substrates.

FIG. 2 is a cross-sectional view of a part of the conventional door 20, wherein the door 20 includes a cover 22 and a bottom plate 23. The cover 22 and the bottom plate 23 are coupled to each other to form an accommodating space S1 for accommodating the plurality of lock structures 21 and the rotating cam, wherein a side of the door 20, that is, a sidewall extending from a periphery of the bottom plate 23 toward the cover 22, has a plurality of openings OP, each opening OP respectively corresponds in position to the lock structures 21, so that the end portions 24 of the lock structures 21 protrude out of the door 20 from the accommodating space S1 at the locked position, and the end portions 24 of the lock structures 21 retract from the accommodating space S1 into the door 20 entirely at the unlocked position.

Regarding the conventional substrate carrier 10, since the lock structures 21 of the door 20 or the lock portions 14 of the outer housing 11 exist a slight tolerance in the manufacture, the lock structures 21 in operation (i.e., the lock structures 21 moving between the unlocked position and the locked position) produce an inclination angle 0° while the lock structures 21, the cover 22 and the bottom plate 23 are operating in conjunction with each other. The inclination angle 0° is a phenomenon results from the rapid protrusion of the end portions 24 of the lock structures 21 from the openings OP to the exterior of the door 20 during the rotation of the rotating cam. However, the excessive magnitude of the inclination angle 0° may result in the inability of the lock structures 21 to align with the lock portions 14 of the outer housing 11, resulting in the end portions 24 of the tilted lock structures 21 collide with peripheral structures of the lock portions 14. The collision leads to generation of particles. Furthermore, the end portions 24 of the lock structures 21 will collide with outer edges of the lock portions 14 or the openings OP of the door 20 due to the inclination angle 0° during operation, resulting in the end portions 24 failing to extend smoothly into the lock portions 14 of the outer housing 11 or failing to retract from the openings OP of the door 20, causing the door 20 falling from the outer housing 11.

In conclusion, a drawback of the prior art lies in the tolerance between the substrate carrier 10 and each of the lock structures 21, so that the lock structures 21 tilt inappropriately relative to the cover 22 or bottom plate 23 of the door 20. Furthermore, during the operational process, a rapid movement will result in a larger amplitude of the inclination angle 0°, causing a less smooth operation for lock, and the door 20 of the substrate carrier 10 is difficult to be opened or closed and likely to be dropped.

### SUMMARY OF THE INVENTION

It is an objective of the disclosure to provide a door having a stabilization mechanism for a lock, the door is suitable for a substrate carrier, the door comprising a bottom plate, a cover, the bottom plate and the cover define a accommodating space for accommodating a plurality of lock structures, each lock structure configured to move between an unlocked position and a locked position; a limiting structure is disposed between the lock structure and the cover, and the limiting structure provides an elastic force corresponding to a displacement of the lock structure between the unlocked position and the locked position, such that the lock structure is maintained to move at a horizontal level under the elastic force.

Another objective of the disclosure is to provide a substrate carrier comprising the door and an outer housing, the outer housing is connected to the door by the lock structures to form a receiving space for receiving a substrate.

In a specific embodiment, the door further comprises a plurality of supporting posts disposed between the bottom plate and the cover, wherein the limiting structure comprises: a fixing portion socked to one of the supporting posts; and an elastic leg extending from the fixing portion and touching against the lock structures.

In a specific embodiment, the limiting structure is connected to an inner wall of the cover, and the limiting structure has a fixing portion and an elastic leg, two ends of the fixing portion are connected to the inner wall of the cover and the elastic leg, respectively, and the elastic leg extends from one end of the fixing portion and touches against the lock structures.

In a specific embodiment, the cover has a plurality of through holes, and the limiting structure has an elastic leg, the elastic leg is connected to inner wall of the through hole and touching against the lock structure.

In a specific embodiment, an end portion of the elastic leg has a bent portion, and a bottom of the bent portion touches against the lock structures.

In a specific embodiment, an end portion of the bent portion has an upwardly bent portion positioned distal to the fixing portion.

In a specific embodiment, a width of an end portion of the elastic leg is less than a width of an end portion of the lock structure.

In a specific embodiment, the elastic leg comprises an extension portion and the end portion that extend from the fixing portion, the extension portion and the end portion have a continuously variable width and length, the width of the end portion is greater than the extension portion.

In a specific embodiment, the fixing portion has a plurality of bumps, the fixing portion is in contact with an inner wall of the cover through the bumps.

In a specific embodiment, the limiting structure extends from the cover or the bottom plate toward a locking hole defined on a lateral side of the door.

In a specific embodiment, the lock structures each have a plurality of stopping portions, and the bottom plate configures a plurality of supporting posts, each of the supporting posts are respectively engaging with each of the stopping portions for limiting position, the supporting posts limiting a linear displacement of the stopping portions while the lock structures are moving, thereby defining the unlocked position and the locked position.

In a specific embodiment, wherein the limiting structure extends from a top side of the lock structure toward the unlocked position and the locked position, an end portion of the limiting structure touches against an inner wall of the cover, and the lock structure have a buffer portion for receiving a portion of the limiting structure while the limiting structure touches against an inner wall of the cover and undergoes elastic deformation, so as to prevent friction generating from the limiting structure contacting with the lock structure.

In a specific embodiment, the outer housing of the substrate carrier has an opening end, with a plurality of lock portions disposed on an inner side of the opening end, the lock portions are designed to match the lock structures, and the end portions of the lock structures correspond in position to the lock portions, thereby presenting the unlocked position or the locked position according to displacement status of the lock structures.

### BRIEF DESCRIPTION OF THE DRAWINGS

The disclosure is depicted by drawings and described below to allow persons skilled in the art to gain insight into the disclosure. Non-restrictive, non-exhaustive embodiments of the disclosure are explained according to the drawings. The drawings are not necessarily drawn to scale but are aimed at disclosing the structural features and principles of the disclosure.

FIG. 1 (PRIOR ART) is a schematic view of a conventional substrate carrier.

FIG. 2 (PRIOR ART) is a cross-sectional view taken along line A-A of FIG. 1.

FIG. 3 is a front view of a door of the disclosure.

FIG. 4 is an exploded view of the door of the disclosure.

FIG. 5 is a schematic view of an internal framework of the door of the disclosure, omitting a cover.

FIG. 6 is a top view of a limiting structure according to the disclosure.

FIG. 7 is a side view of the limiting structure according to the disclosure.

FIG. 8 is an enlarged perspective view of part B of FIG. 5.

FIG. 9 is a schematic view of a lock structure at an unlocked position.

FIG. 10 is a schematic view of the lock structure between the unlocked position and a locked position.

FIG. 11 is a schematic view of the lock structure at the locked position.

FIG. 12 is a schematic view of a door according to a second embodiment of the disclosure.

FIG. 13 is a perspective view of a lock structure and a limiting structure according to a third embodiment of the disclosure.

FIG. 14 is a schematic view of the door according to the third embodiment of the disclosure.

### DETAILED DESCRIPTION OF THE EMBODIMENTS

The disclosure is depicted by accompanying drawings, illustrated by specific embodiment and described below. However, the subject matters claimed by the disclosure can be implemented in various ways; hence, the subject matters falling within the scope of or claimed by the disclosure are not restricted to any specific embodiments of the disclosure. The specific embodiments of the disclosure serve illustrative purposes only. Likewise, the disclosure is aimed at defining reasonably broad scope of the subject matters falling within the scope of or claimed by the disclosure.

The expression “in an embodiment” used herein does not necessarily refer to the same specific embodiment. Furthermore, the expression “in other (a few/some) embodiments” used herein does not necessarily refer to different specific embodiments. The expressions are aimed at, for example, enabling the claimed subject matter to include the combination of all or part of exemplary, specific embodiments. The meanings of the expression “coupled” used herein include “directly connected” or “indirectly connected,” for example, “socketed”.

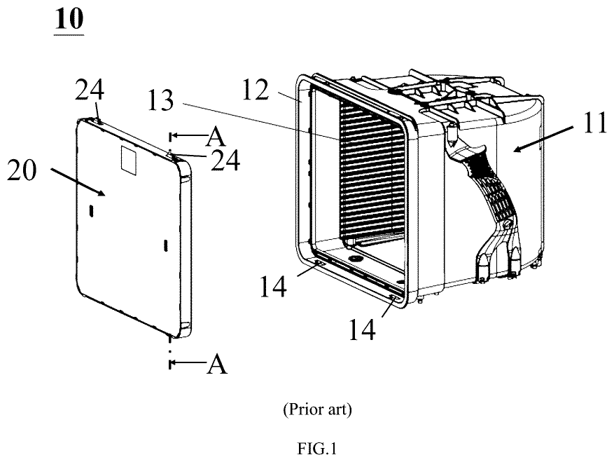

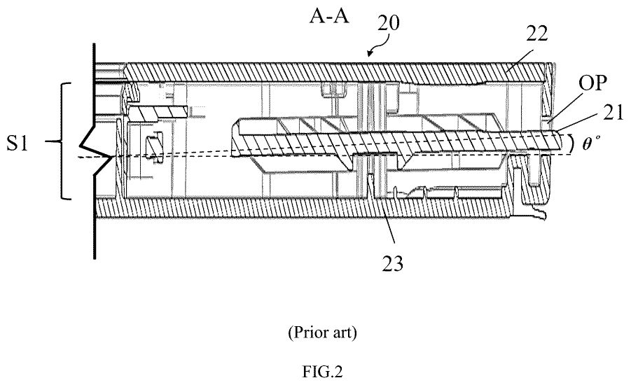

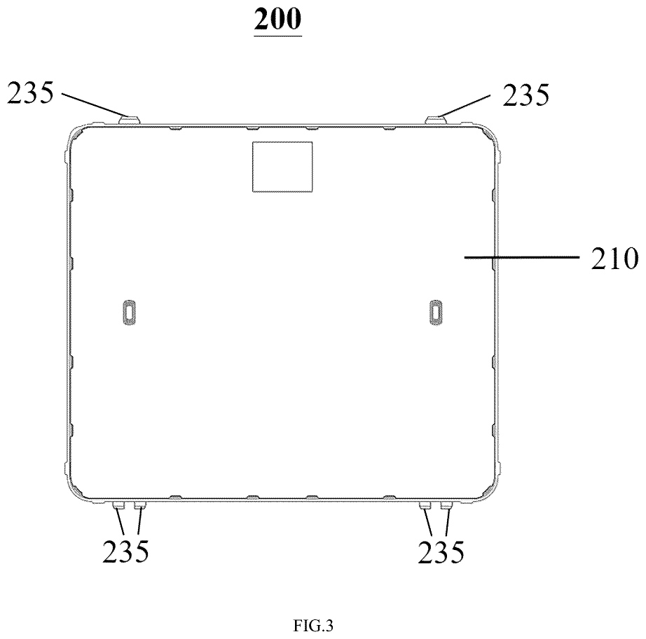

FIG. 3 through FIG. 5 show a door 200 disposed in a substrate carrier and having a stabilization mechanism for a lock according to the disclosure, wherein the substrate carrier of the disclosure corresponds to the substrate carrier 10 described above and thus is, for the sake of brevity, not reiterated. According to the disclosure, the substrate carrier comprises a door 200, the door 200 comprises a cover 210 and a bottom plate 220. The cover 210 and the bottom plate 220 are coupled to form the door 200. The cover 210 and the bottom plate 220 define an accommodating space for accommodating a plurality of lock structures 230. A limiting structure 240 is disposed between the lock structure 230 and the cover 210 and described later. In a preferred embodiment of the disclosure, the accommodating space accommodates four lock structures 230 which are divided into two groups, and each group consists of two lock structures 230 arranged symmetrically to each other, and each lock structure 230 has a connection end (not shown). The connection ends of each group of the lock structures 230 are jointly connected to a rotation mechanism 250. The rotation mechanism 250 is rotatably connected to a fixing post 225 on the bottom plate 220, the rotation mechanism 250 rotates under an external force to control the group of the lock structures 230 moving between an unlocked position and a locked position. The unlocked position is defined by the plurality of lock structures 230 completely receiving in the door 200. The locked position is defined by a position which each of the end portion 235 of the plurality of lock structures 230 protrudes out of locking hole 221 on one side of the bottom plate 220. More specifically, the position of the locking holes 221 is designed to match a plurality of lock portions 14 of the outer housing 11 (as shown in FIG. 1), and the end portions 235 of the lock structures 230 also correspond in position to the lock portions 14, allowing the lock structures 230 to protrude or retract and thereby presenting the unlocked position or the locked position, respectively. The number and structural features of the lock structures 230 are subject to be designed as needed and thus are not limited by the disclosure.

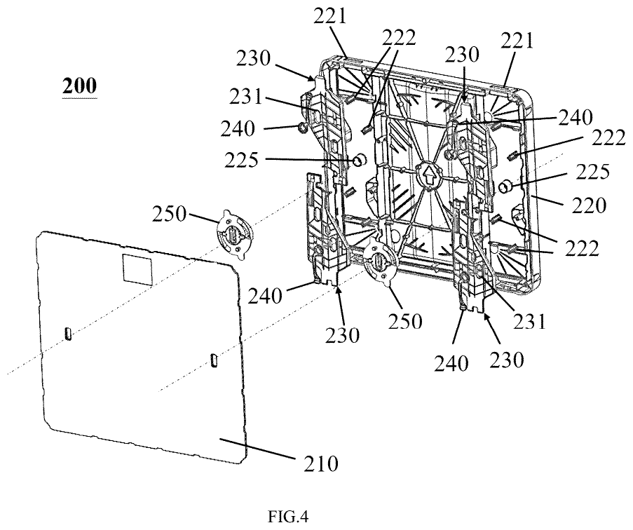

According to the disclosure, in the first embodiment illustrated by FIG. 4 and FIG. 8, each lock structure 230 has at least one stopping portion 231, and a plurality of supporting posts 222 are disposed between the bottom plate 220 and the cover 210, wherein the supporting posts 222 are mounted on the bottom plate 220 or the cover 210; alternatively, the supporting posts 222 extend from the bottom plate 220 toward the cover 210; alternatively, the supporting posts 222 extend from the cover 210 toward the bottom plate 220. The aforesaid variable technical features of the plurality of supporting posts 222 are subject to be designed as needed and thus are not limited by the disclosure. When the cover 210 and the bottom plate 220 are coupled together, a free distal end of each supporting post 222 is connected to a corresponding structure of the cover 210 or the bottom plate 220. In this embodiment, the supporting posts 222 are disposed on the bottom plate 220. The supporting posts 222 are configured as follows: When the lock structures 230 are accommodated in the accommodating space S1, the supporting posts 222 respectively engage with the stopping portions 231 to limit position, and a plurality of supporting posts 222 limit the linear displacement of a plurality of stopping portions 231, thereby defining the movement stroke of the lock structure 230 so as to define the unlocked position and the locked position. In a specific practice, the supporting posts 222 oppose the lock structures 230 and limit the displacement of the lock structures 230 while the lock structures 230 are moving. The unlocked position (shown in FIG. 8) is defined when the supporting posts 222 are positioned in the stopping portions 231 and contact with the inner wall where the stopping portions 231 proximate to the locking holes 221. The locked position (shown in FIG. 5) is defined when the supporting posts 222 are positioned in the stopping portions 231 and contact with the inner wall where the stopping portions 231 are distal to the locking holes 221. In other words, the movement stroke of the lock structures 230 is determined by a length of the stopping portions 231.

Compared with the prior art, the door 200 of the disclosure further comprises a plurality of limiting structures 240, each of the limiting structure 240 disposed in the space between the cover 210 and lock structure 230. In an embodiment, the limiting structures 240 are coupled to the supporting posts 222 and thereby disposed between the cover 210 and lock structure 230. The limiting structure 240 provides an elastic force corresponding to the displacement by the lock structures 230 moving between the unlocked position and the locked position. The horizontal level of the lock structures 230 is maintained within an appropriate range under the elastic force. Preferably, the lock structures 230 maintain moving at a horizontal level under the elastic force. During a locking operation, the end portions 235 of the lock structures 230 can precisely align with a target structure, such as the end portions 235 protrude out of the locking holes 221 of the bottom plate 220 and face the lock portions 14 of the outer housing 11 of FIG. 1, and the lock structures 230 being touched against from the deformation of the limiting structures 240 under the elastic force for maintaining the lock structures 230 moving at a horizontal level (for example, moving upward toward the cover 210), so that the end portions 235 being precisely aligned for lock. During a unlocking operation, the lock structures 230 being touched against from the deformation of the limiting structures 240 under the elastic force for maintaining the lock structures 230 (for example, moving downward away from the cover 210), such that the end portions 235 retract into the accommodating space S1 via the locking holes 221 of the bottom plate 220 for achieving the unlocking operation. Therefore, the door 200 can be smoothly operated for lock and unlock within the outer housing 11 of the substrate carrier 10, thereby solving issues of inadvertent collision with the lock portions 14 of the outer housing 11 or impact near the locking hole 221, which could result in difficulties in smoothly locking or unlocking the door 200.

Functional features of the limiting structures 240 in the door 200 are described above. Embodiments of fine structural features of the limiting structures 240 and constituent elements disposed between each lock structure 230 and the cover 210 are described below. A number of the limiting structures 240 disposed between each lock structure 230 and the cover 210 is subject to changes as needed and thus is not limited by the disclosure.

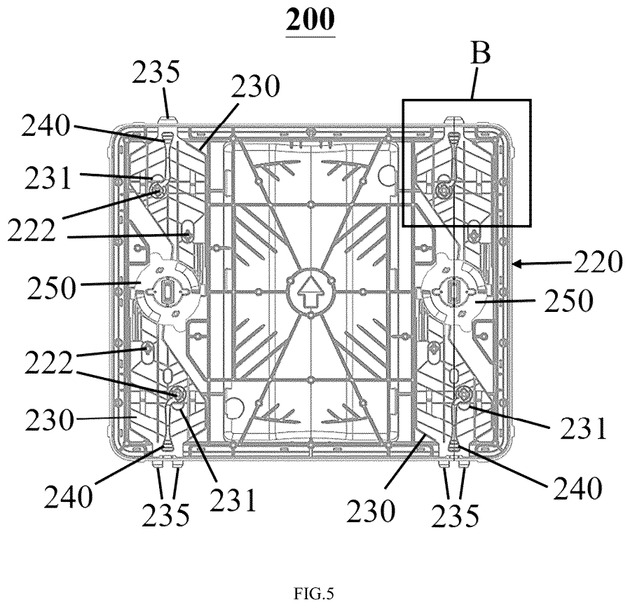

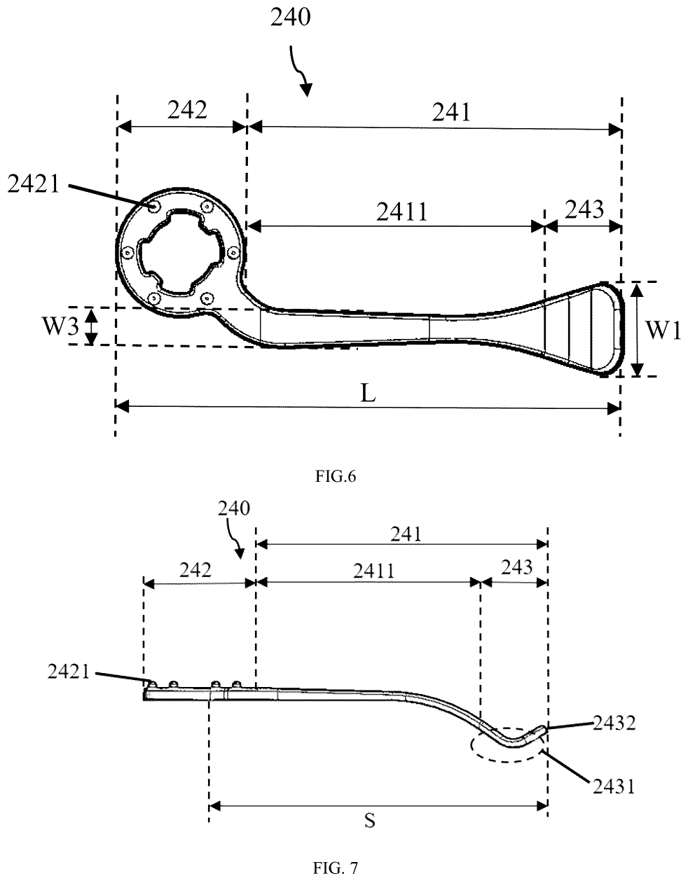

Referring to FIG. 4 through FIG. 8, the disclosure is implemented in an embodiment. FIG. 6 and FIG. 7 are a top view and a side view of the limiting structures of the disclosure, respectively. FIG. 8 is an enlarged perspective view of part B of FIG. 5. According to the disclosure, the limiting structure 240 comprises an elastic leg 241 and a fixing portion 242. Two ends of the fixing portion 242 are connected to the inner wall (facing the accommodating space S1) of the cover 210 and the elastic leg 241, respectively. The elastic leg 241 extends from one end of the fixing portion 242 and touches against the lock structure 230. Referring to FIG. 6 and FIG. 7, the elastic leg 241 comprises an extension portion 2411 and an end portion 243, both of which extend from the fixing portion 242, the extension portion 2411 and the end portion 243 have a continuously variable width and length. The end portion 243 is substantially spoon-shaped. The end portion 243 has a bent portion 2431 and an upwardly bent portion 2432. The bent portion 2431 is disposed between the extension portion 2411 and the upwardly bent portion 2432, the upwardly bent portion 2432 positioned distal to the fixing portion 242. A width W1 of the end portion 243 is greater than a width W3 of the extension portion 2411.

Referring to FIG. 7 and FIG. 8, the width W1 of the end portion 243 of the elastic leg 241 is less than a width W2 of the end portion of the lock structure 230 such that the touching area of the end portion 243 is sufficiently enough to enhance sliding stabilization. In a preferred embodiment, the fixing portion 242 is ring-shaped and socketed around the outer circumference of the supporting post 222, such that one end of the limiting structure can be fixed to the supporting post 222. The fixing portion 242 has a plurality of bumps 2421 facing the inner wall of the cover 210, wherein the plurality of bumps 2421 are arranged in a ring-shaped pattern and spaced part from each other, so as to provide a uniform abutting force. By the plurality of bumps 2421, a contact area between the inner wall of the cover 210 and the fixing portion 242 is reduced, so as to avoid the particle generation from large area friction between the fixing portion 242 and the inner side of the cover 210. In a preferred embodiment, the bumps 2421 are made of an elastic material and formed integrally with the fixing portion 242. In a preferred embodiment, the bump 2421 are spherical in shape as a point contact between each bump 2421 and the inner wall of the cover 210, so as to reduce range of the contact area, but the disclosure is not limited thereto.

The fixing portion 242 of the limiting structure 240 is made of a material of high rigidity, and the elastic leg 241 is made of an elastic material. Since the elastic leg 241 is made of an elastic material, a length L of the limiting structure 240 correlates with a magnitude of the elastic force. More specifically, when the length L of the limiting structure 240 is increasing (that is, the elastic stroke S of the extension portion 2411 of the elastic leg 241 is longer), the generated elastic tolerance (also known as elasticity allowance) is greater, and thus the elastic strength of the limiting structure 240 acting on the lock structure 230 in the course of sliding is less. Conversely, when the length L of the limiting structure 240 is decreasing (that is, the elastic stroke S of the extension portion 2411 of the elastic leg 241 is shorter), the relative rigidity is greater, the generated elastic tolerance is less, and thus the elastic strength of the limiting structure 240 acting on the lock structure 230 in the course of the slide is greater, resulting in the greater magnitude of force provided while the lock structure is sliding. The elastic tolerance (also known as elasticity allowance) of the disclosure means a range of deviations or variations that can be tolerated by a system or component under normal use conditions. According to the disclosure, the elastic tolerance (also known as elasticity allowance) refers to capability of the lock structure 230 to function well without tilting severely or malfunctioning despite manufacturing-induced variations or errors.

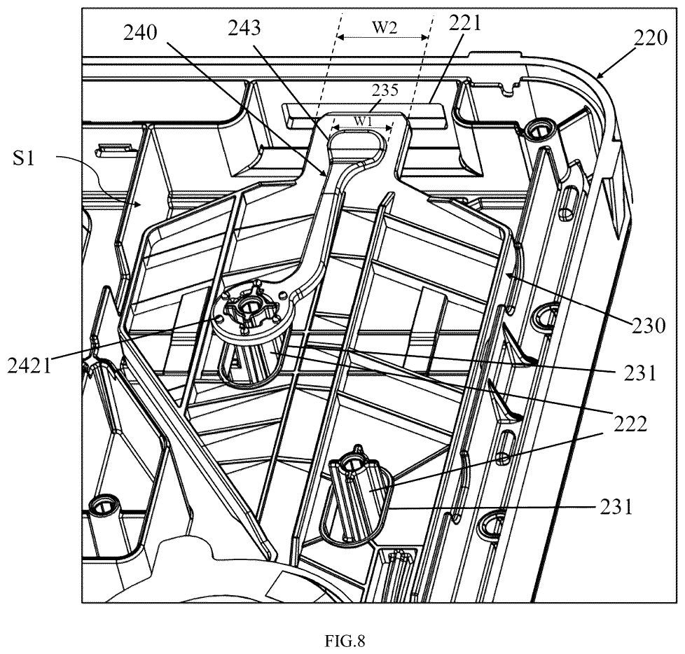

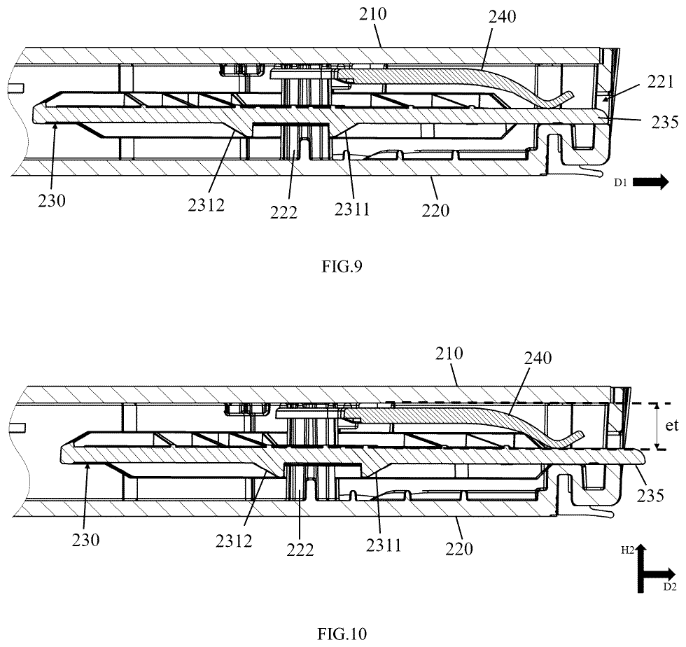

The fine structural features of the limiting structure 240 are described above. Referring to FIG. 9 through FIG. 11, there are shown schematic views of the lock structure switched from the unlocked position to the locked position, further illustrating an important functional role played by an elastic force provided by the limiting structure 240 in keeping the lock structure 230 moving at a horizontal level. FIG. 9 is a schematic view of the lock structure 230 at the unlocked position. FIG. 10 is a schematic view of the lock structure 230 between the unlocked position and the locked position. FIG. 11 is a schematic view of the lock structure 230 at the locked position.

Referring to FIG. 8 and FIG. 9, the limiting structure 240 provides an elastic force on an upper surface of the lock structure 230, and a bottom of the bent portion 2431 of the elastic leg 241 touches against the upper surface (i.e., inner wall facing the cover 210) of the lock structure 230. A height distance between the upwardly bent portion 2432 and the upper surface of the lock structure 230 is maintained. Thus, during the slide, the bent portion 2431 has a smaller contact area with the lock structure 230, thereby avoiding a scratching on the lock structure 230 and particles generation. In a preferred embodiment of the disclosure, the limiting structure 240 is made of an elastic material and integrally formed, but the disclosure is not limited thereto.

After the cover 210 and the bottom plate 220 have been coupled to each other, the end portion 235 of the lock structure 230 is pushed toward an inner surface of the bottom plate 220 under the elastic force of the limiting structure 240. An operation of the rotation mechanism 250 shown in FIG. 5 enables the lock structure 230 to start sliding from the unlocked position to the locked position and moving at a horizontal level in the direction of lateral displacement D1 shown in FIG. 9. At this point in time, the supporting posts 222 limit linear displacement of the stopping portions 231; when the lock structure 230 moves in the direction of lateral displacement D1, a first end 2311 of the stopping portion 231 of the lock structure 230 undergoes linear displacement toward the locking holes 221 until displacement of a second end 2312 of the stopping portion 231 is limited by the supporting posts 222, and the end portions 235 of the lock structures 230 starts passing through the locking holes 221 defined on the lateral side of the bottom plate 220. The first end 2311 of the stopping portion 231 is positioned proximate to the locking holes 221. The second end 2312 of the stopping portion 231 is positioned distal to the locking holes 221.

Referring to FIG. 10, under the elastic force provided by the limiting structure 240, the lock structure 230 counteracts perpendicular displacement (vertical displacement H2) resulting from the operation of the rotation mechanism 250, and thus the lock structure 230 keeps moving at a horizontal level (in the direction of lateral displacement D2) while sliding continuously; at this point in time, parts of the end portion 235 of the lock structure 230 passes through the locking hole 221 and protrude out of the bottom plate 220.

Referring to FIG. 11, when the lock structure 230 slides from a position shown in FIG. 10 to the locked position, the lock structure 230 moves at a horizontal level (in the direction of lateral displacement D3) under the elastic force provided by the limiting structure 240 corresponding to a displacement by the lock structure 230, that is, the end portion 235 of the lock structure 230 to completely protrude out of the locking holes 221 of the bottom plate 220. The elastic force of the limiting structure 240 is less than a vertical force generated as a result of the operation of the rotation mechanism 250 when the lock structure 230 is near the locked position, and thus the lock structure 230 undergoes perpendicular displacement (vertical displacement H3; Owing to the rotation mechanism 250, the end portion 235 of the lock structure 230 completely protrudes out of the locking hole 221 of the bottom plate 220 and then tilts upward as shown in FIG. 11.) Therefore, the end portion 235 of the lock structure 230 adjusts a displacement status according to the elastic force provided by the limiting structure 240 and thus is still applicable to the lock portions 14 of the damaged outer housing 11 (as shown in FIG. 1) even in the presence of tolerance, allowing the end portions 235 of the lock structures 230 to precisely align with the lock portions 14 of the outer housing 11 in order to open/close the door. To ensure that the lock structures 230 at the locked position tilt less, it is feasible to select a shape, length or material of the limiting structure 240 appropriately to provide a sufficient elastic force and thereby counteract the vertical displacement H3 of the rotation mechanism 250.

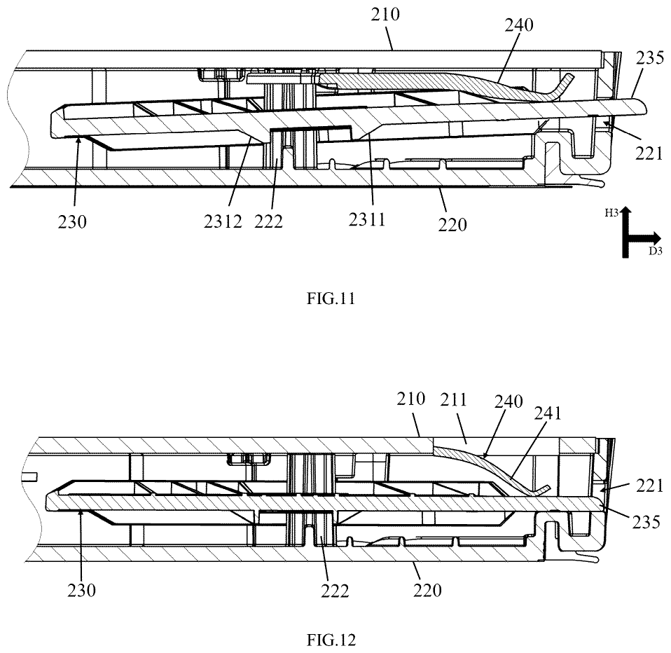

Like the aforesaid door, a door in a second embodiment of the disclosure as illustrated by FIG. 12 has the cover 210, the bottom plate 220, and a lock structure 230 disposed therebetween. According to the lock structure 230 is driven by the operational of aforesaid rotation mechanism 250, and the linear displacement of the lock structure 230 is limited by restraining the supporting posts 222 between the first end 2311 and the second end 2312 of the stopping portion, so that the lock structure 230 moves between the unlocked position and the locked position. The differences between the second embodiment and the first embodiment are described herein, but elements the first and second embodiments have in common are not reiterated. The cover 210 has a plurality of through holes 211, and the limiting structure 240 has the elastic leg 241, the elastic leg 241 connects to the inner walls of the plurality of through holes 211 and extends outward from the inner walls of the plurality of through holes 211 to touch against the upper surface of the lock structure 230. The bottom of the bent portion 2431 of the elastic leg 241 touches against the upper surface of the lock structure 230 (with the upwardly bent portion 2432 facing the plurality of through holes 211 of the cover 210), so as to maintain a height distance between the upwardly bent portion 2432 and the upper surface of the lock structure 230. By this configuration, the limiting structure 240 provides a variable elastic force corresponding to the displacement by the lock structure 230 such that the lock structure 230 moves at a horizontal level. The structural features and functions of the elastic leg 241 in the second embodiment are the same as those of its counterpart in the first embodiment and thus are not reiterated. In the second embodiment, the limiting structure 240 is connected or coupled to the inner wall of the cover 210 by any possible means. For example, the elastic leg 241 is coupled to the inner wall of the through hole 211. Alternatively, the elastic leg 241 integrally extends from the inner wall of the through holes 211 and touches against the lock structure 230. Alternatively, a coupling structure, such as a positioning slot, is disposed on the inner wall of the cover 210 and corresponds in shape and position to the limiting structure 240 to allow the limiting structure 240 to be coupled to the inner wall of the cover 210.

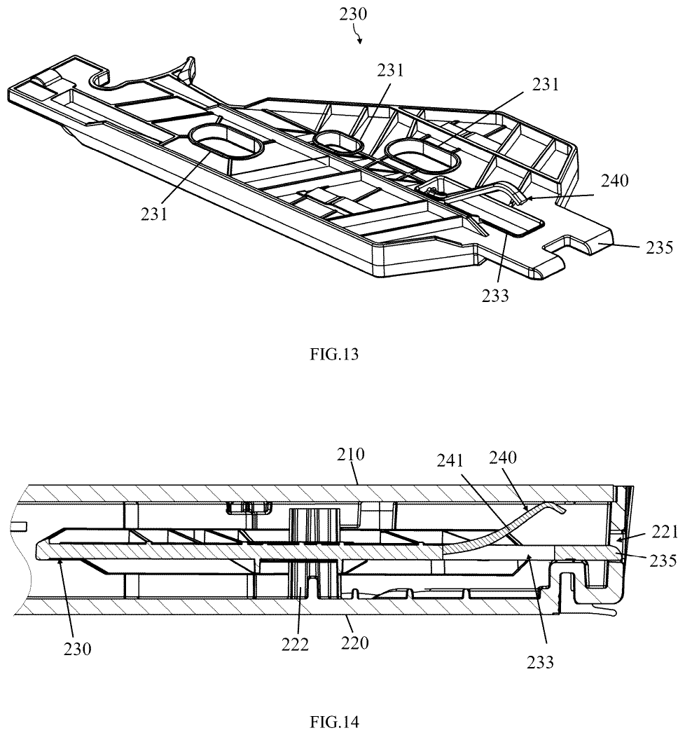

FIG. 13 and FIG. 14 depict the door according to a third embodiment of the disclosure. The differences between the third embodiment and the first embodiment are described herein, but elements in common in the first and third embodiments are not reiterated. FIG. 13 is a perspective view of the lock structure and the limiting structure according to the third embodiment of the disclosure. FIG. 14 is a schematic view of the door according to the third embodiment of the disclosure. In the third embodiment, the limiting structure 240 extends from the top side of the lock structure 230 toward the unlocked position and the locked position. The limiting structure 240 has the elastic leg 241, and the elastic leg 241 connects to the top side of the lock structure 230 and touches against the inner wall of the cover 210. The bottom of the bent portion 2431 of the elastic leg 241 touches against the inner wall of the cover 210 (with the upwardly bent portion 2432 facing the bottom plate 220), and a height distance between the upwardly bent portion 2432 and the inner wall of the cover 210 is maintained. The lock structure 230 has a buffer portion 233; in a preferred embodiment, the buffer portion 233 is a through hole. By this configuration, the limiting structure 240 provides a variable elastic force corresponding to the displacement by the lock structure 230 while the lock structure 230 is moving. When the limiting structure 240 touches against the inner wall of the cover 210 and thus undergoes elastic deformation, the buffer portion 233 receives part of the limiting structure, that is, part of the elastic leg 241, to prevent generating friction from the limiting structure 240 directly contacting with the lock structure 230, and to allow the lock structure 230 moving at a horizontal level. The structural features and functions of the elastic leg 241 in the third embodiment are the same as those of its counterpart in the first embodiment and thus are not reiterated.

In conclusion, according to the disclosure, the limiting structure is disposed between a lock structure and a cover. Regardless of its structural design and configuration, the limiting structure can fall within the scope of the appended claims of the disclosure as long as it provides an elastic force corresponding to the displacement by the lock structure moving between the unlocked position and the locked position and allows the lock structure to keep moving at a horizontal level under the elastic force. The structural design of the limiting structure in this invention effectively addresses the industry-wide issue where the lock structure rapidly extends with a significant inclination angle 0° for the locking action during the operation of the door of the substrate carrier, resulting in the door failing to be precisely lock into the substrate carrier, and challenges in opening and closing, and even potential of the door drop.

What is claimed is:

1. A door having a stabilization mechanism for a lock, the door is suitable for a substrate carrier, the door comprising:
a bottom plate and a cover, the bottom plate and the cover define a accommodating space for accommodating a plurality of lock structures, each lock structure configured to move between an unlocked position and a locked position; and
a limiting structure disposed between the lock structure and the cover, and the limiting structure provides an elastic force corresponding to the displacement of the lock structure between the unlocked position and the locked position, such that the lock structure is maintained to move at a horizontal level under the elastic force.

2. The door of claim 1, further comprising a plurality of supporting posts disposed between the bottom plate and the cover, wherein the limiting structure comprises:
a fixing portion socked to one of the supporting posts; and
an elastic leg extending from the fixing portion and touching against the lock structures.

3. The door of claim 1, wherein the limiting structure is connected to an inner wall of the cover and has a fixing portion and an elastic leg, two ends of the fixing portion are connected to the inner wall of the cover and the elastic leg, respectively, and the elastic leg extends from one end of the fixing portion and touches against the lock structures.

4. The door of claim 1, wherein the cover has a plurality of through holes, and the limiting structure has an elastic leg, the elastic leg is connected to inner wall of the through hole and touching against the lock structure.

5. The door of claim 2, wherein an end portion of the elastic leg has a bent portion, and a bottom of the bent portion touches against the lock structures.

6. The door of claim 3, wherein an end portion of the elastic leg has a bent portion, and a bottom of the bent portion touches against the lock structures.

7. The door of claim 4, wherein an end portion of the elastic leg has a bent portion, and a bottom of the bent portion touches against the lock structures.

8. The door of claim 5, wherein an end portion of the bent portion has an upwardly bent portion positioned distal to the fixing portion.

9. The door of claim 5, wherein the elastic leg comprises an extension portion and the end portion that extend from the fixing portion, the extension portion and the end portion have a continuously variable width and length, the width of the end portion is greater than the extension portion.

10. The door of claim 2, wherein a width of an end portion of the elastic leg is less than a width of an end portion of the lock structure.

11. The door of claim 2, wherein the fixing portion has a plurality of bumps, the fixing portion is in contact with an inner wall of the cover through the bumps.

12. The door of claim 1, wherein the limiting structure extends from the cover or the bottom plate toward a locking hole defined on a lateral side of the door.

13. The door of claim 1, wherein each of the lock structures has a plurality of stopping portions, and the bottom plate configures a plurality of supporting posts, each of the supporting posts are respectively engaging with each of the stopping portions for limiting position, the supporting posts limiting a linear displacement of the stopping portions while the lock structures are moving, thereby defining the unlocked position and the locked position.

14. The door of claim 1, wherein the limiting structure extends from a top side of the lock structure toward the unlocked position and the locked position, an end portion of the limiting structure touches against an inner wall of the cover, and each of the lock structures has a buffer portion for receiving a portion of the limiting structure as soon as the limiting structure abuts against an inner wall of the cover and undergoes elastic deformation, so as to prevent friction generating from the limiting structure contacting with the lock structure.

15. A substrate carrier, comprising:
the door of claim 1; and
an outer housing connected to the door by the lock structures to form a receiving space for receiving a substrate.

16. The substrate carrier of claim 13, wherein the outer housing has an opening end, with a plurality of lock portions disposed on an inner side of the opening end, the lock portions are designed to match the lock structures, and the end portions of the lock structures correspond in position to the lock portions, thereby presenting the unlocked position or the locked position according to displacement status of the lock structures.
